(19) United States
(12) Patent Application Publication
(10) Pub. No.: US 2024/0194571 A1
(43) Pub. Date: Jun. 13, 2024

(54) LEAD FRAME INCLUDING LEAD WITH GROOVE FORMED THEREIN

(71) Applicant: HAESUNG DS CO., LTD., Changwon-si (KR)

(72) Inventors: Do Yeon WOO, Changwon-si (KR); Seok Kyu SEO, Gyeongsangnam-do (KR); Byoungchul CHOI, Gyeongsangnam-do (KR)

(21) Appl. No.: 17/620,053

(22) PCT Filed: Jul. 1, 2021
(86) PCT No.: PCT/KR2021/008320

§ 371 Date: Feb. 14, 2024

(30) Foreign Application Priority Data
Jun. 28, 2021 (KR) 10-2021-0084157

(51) Int. Cl. H01L 23/495

(52) U.S. Cl. CPC H01L 23/49548

(57) ABSTRACT

According to an aspect of the present disclosure, provided is a lead frame including a plurality of lead with a lead groove formed therein; and a dambar arranged between the leads to connect the leads, wherein a thickness of the dambar arranged between the leads has at least two thickness values, and a dambar groove is formed between a thickest portion of the dambar and the lead neighboring the thickest portion of the dambar.

### TECHNICAL FIELD

The present disclosure relates to a lead frame including a lead with a groove formed therein.

### BACKGROUND ART

A lead frame is a metal substrate, on which a semiconductor chip is arranged, and has been widely used for manufacturing of a semiconductor package.

Recently, to increase mounting reliability of a semiconductor package, technology related to a wettable flank structure is actively under development.

A wettable flank structure is a structure of forming a sufficient solder fillet at a lead bonding part by cutting a part of an edge of a rear surface of a lead frame. An inspector may easily check the mounting reliability of semiconductor package by inspecting an appearance condition of the structure.

Lead frames adopting the wettable flank structure may be largely classified into two types of a step-cut lead frame in which a step is formed on a lead and a hollow-groove lead frame in which a groove is formed in a lead.

As a lead frame adopting the wettable flank structure has a step or a groove, stiffness of the lead frame may deteriorate so that, during design, thickness and shape of a dambar are designed to secure sufficient stiffness. In other words, when a dambar that supports a lead does not have sufficient stiffness, a lead frame may bent so that manufacturing of a semiconductor package may have a problem.

U.S. patent Ser. No. 10/930,581 discloses a semiconductor package including a wettable conductive layer that covers an encapsulation material.

### DESCRIPTION OF EMBODIMENTS

### Technical Problem

Provided is a lead frame having an improved dambar structure.

### Solution to Problem

According to an aspect of the present disclosure, a lead frame includes a plurality of lead with a lead groove formed therein and a dambar arranged between the leads to connect the leads, wherein a thickness of the dambar arranged between the leads has at least two thickness values, and a dambar groove is formed between a thickest portion of the dambar and the lead neighboring the thickest portion of the dambar.

### Advantageous Effects of Disclosure

In a lead frame according to an aspect of the present disclosure, the lead frame may have improved quality because straightness of a lead is improved during an etching process for manufacturing the lead frame.

Furthermore, in a lead frame according to an aspect of the present disclosure, during a sawing process for singulation of a semiconductor package, ease of work may be improved and burr generation may be reduced.

### BRIEF DESCRIPTION OF DRAWINGS

FIG. 1 is a schematic perspective view of a bottom surface of a semiconductor package, according to an embodiment of the present disclosure.

FIG. 2 is a schematic plan view of a lead frame according to an embodiment of the present disclosure.

FIG. 3 is a schematic view of a portion A of FIG. 2 by enlarging the same.

FIG. 4 is a schematic cross-sectional view taken along line I-I of FIG. 3.

FIGS. 5 and 6 are schematic views of modified examples of a lead and a dambar of a lead frame, according to an embodiment of the present disclosure.

FIG. 7 is a schematic view of a lead and a dambar of a lead frame according to a comparative example for comparison with the present disclosure.

FIG. 8 is a schematic cross-sectional view taken along line II-II of FIG. 7.

### BEST MODE

According to an aspect of the present disclosure, a lead frame includes a plurality of lead with a lead groove formed therein and a dambar arranged between the leads to connect the leads, wherein a thickness of the dambar arranged between the leads has at least two thickness values, and a dambar groove is formed between a thickest portion of the dambar and the lead neighboring the thickest portion of the dambar.

Here, the lead groove may be applied to a wettable flank structure.

Here, the thickness of a thickest portion of the lead may be the same as the thickness of the thickest portion of the dambar.

Here, the thickness of a portion of the lead where the lead groove is formed may be the same as the thickness of a portion of the dambar where dambar groove is formed.

Here, the shape of an upper surface of the thickest portion of the dambar may be a rectangle.

Here, a part of the sides of the rectangle may be parallel to an extension direction of the lead.

Here, the shape of an upper surface of the thickest portion of the dambar may be a circle.

Here, the shape of an upper surface of the thickest portion of the dambar may be a polygon.

### MODE OF DISCLOSURE

Hereinafter, the embodiments of the present disclosure are described in detail with reference to the accompanying drawings. Furthermore, in the description and the drawings, the constituent elements having substantially the same configurations are indicated by the same reference numerals and redundant descriptions thereof are omitted. In the drawings, to help understanding, an exaggerated portion may be present in the ratio of size or length, and the like.

The present disclosure will be clearer referring to the detailed descriptions below with the drawings. However, the present disclosure may be embodied in many different forms and should not be construed as being limited to the embodiments set forth herein; rather, these embodiments are provided so that this disclosure will be thorough and complete, and will fully convey the concept of the disclosure to those of ordinary skill in the art.

Terms used in the specification are used for explaining a specific embodiment, not for limiting the disclosure. Thus, an expression used in a singular form in the specification also includes the expression in its plural form unless clearly specified otherwise in context. Also, terms such as “comprises” and/or “comprising” may be construed to denote a certain step, operation, constituent element, and/or device, but may not be construed to exclude the existence of or a possibility of addition of one or more other steps, operations, constituent elements, and/or devices. While such terms as “first,” “second,” etc., may be used to describe various components, such components must not be limited to the above terms. The above terms are used only to distinguish one component from another.

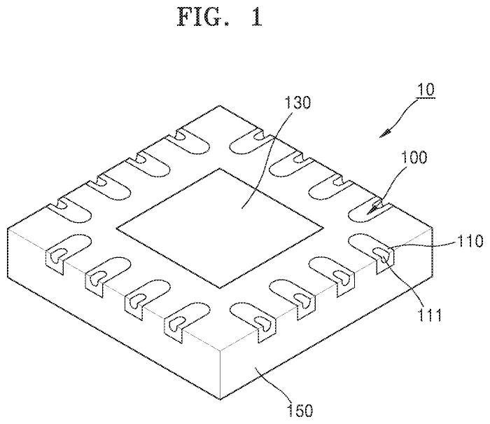

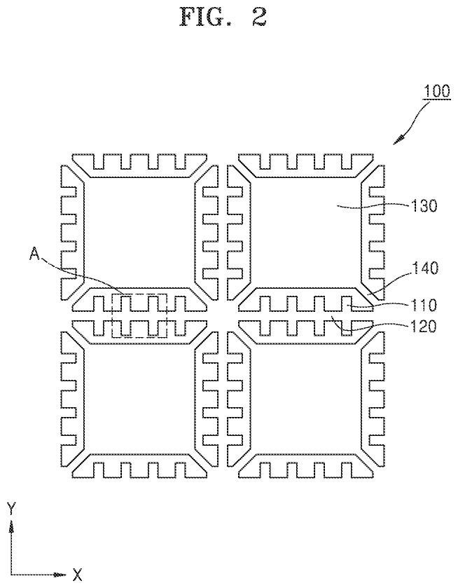

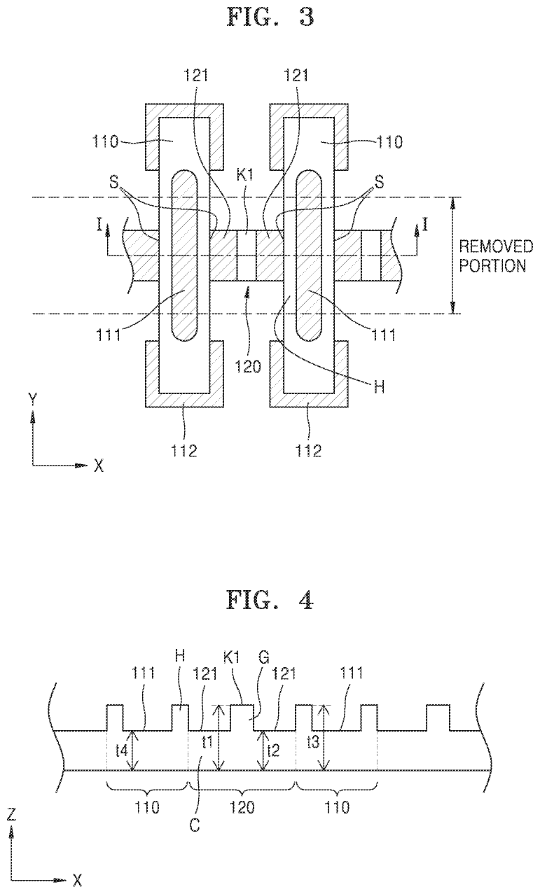

FIG. 1 is a schematic perspective view of a bottom surface of a semiconductor package, according to an embodiment of the present disclosure. FIG. 2 is a schematic plan view of a lead frame according to an embodiment of the present disclosure, FIG. 3 is a schematic view of a portion A of FIG. 2 by enlarging the same, and FIG. 4 is a schematic cross-sectional view taken along line I-I of FIG. 3.

As illustrated in FIG. 1, a semiconductor package 10 according to an embodiment of the present disclosure may include a lead frame 100 of a wettable flank structure. In other words, the lead frame 100 having a wettable flank structure may include a lead 110 in which a lead groove 111 is formed, and the lead groove 111 has a structure that allows a solder fillet to be sufficiently formed during mounting of a semiconductor package on a substrate.

As illustrated in FIG. 2, the lead frame 100 according to the present embodiment may include the lead 110, a dambar 120, a die pad 130, a pad support portion 140.

The shapes of the lead 110, the dambar 120, the die pad 130, and the pad support portion 140 of the lead frame 100 may be formed by etching a material of a base metal. The material of a base metal may include iron, an iron alloy, nickel, a nickel alloy, alloy 42, copper, a copper alloy, and the like. A method of etching the base metal may include a typical method such as a wet etching method, a dry etching method, and the like for forming a lead frame, in which the wet etching method uses an etchant as an etching material, the dry etching method uses a reactive gas, ion, and the like as an etching material.

As illustrated in FIG. 3, the lead groove 111 and a half etching portion 112 are formed in the lead 110.

The lead 110 may include a plurality of leads that are parallel to neighboring leads.

The lead groove 111 formed in the lead 110 is applied to a wettable flank structure. In other words, in a process of mounting the semiconductor package 10 on the substrate, as the lead groove 111 is filled with solder, a sufficient solder fillet is formed.

The half etching portion 112 is formed at an edge of an end portion of the lead 110, ad assists support of the lead 110 by being coupled to a mold resin 150.

According to the present embodiment although the half etching portion 112 is formed on the lead 110, the present disclosure is not limited thereto. In other words, no half etching portion may be formed in the lead according to according to the present disclosure lead.

The dambar 120 is arranged between the leads 110, and connects and supports the leads 110.

As illustrated in FIGS. 3 and 4, the dambar 120 is not formed to have a uniform thickness, but the thickness of the dambar 120 has at least two thickness values. In other words, the dambar 120 has at least a thickest portion G and a thinnest portion C.

A thickness t1 of the thickest portion G of the dambar 120 is different from a thickness t2 of the thinnest portion C.

The thickness t1 of the thickest portion G of the dambar 120 according to the present embodiment is designed to be the same as a thickness t3 of a thickest portion H of the lead 110.

According to the present embodiment, although the thickness t1 of the thickest portion G of the dambar 120 is designed to be the same as the thickness t3 of the thickest portion H of the lead 110, the present disclosure is not limited thereto. In other words, according to the present disclosure, the thickness t1 of the thickest portion G of the dambar 120 may not be the same as the thickness t3 of the thickest portion H of the lead 110.

A dambar groove 121 is formed between the thickest portion G of the dambar 120 and the lead 110 neighboring the thickest portion G of the dambar 120.

In other words, when viewed in a direction (an X-axis direction) perpendicular to an extension direction (a Y-axis direction) of the lead 110, the dambar groove 121 is formed between the thickest portion G of the dambar 120 and the lead 110 neighboring the same.

The thickest portion G of the dambar 120 performs a function of supplementing stiffness of the lead frame 100. In other words, as the lead groove 111 is formed in the lead 110 of the present embodiment, stiffness may be reduced, and thus, a thick portion of the dambar 120 may supplement stiffness as a whole.

A portion of the dambar 120 where the dambar groove 121 is formed is the thinnest portion C, and the thickness t2 of the thinnest portion C is the same as a thickness t4 of a portion of the lead 110 where the lead groove 111 is formed.

According to the present embodiment, although the thickness t2 of the dambar 120 where the dambar groove 121 is formed is designed to be the same as the thickness t4 of the lead 110 where the lead groove 111 is formed, the present disclosure is not limited thereto. In other words, according to the present disclosure, the thickness t2 of the dambar 120 where the dambar groove 121 is formed may not be the same as the thickness t4 of the lead 110 where the lead groove 111 is formed.

Furthermore, as illustrated in FIG. 3, the shape of an upper surface K1 of the thickest portion G of the dambar 120 is a rectangle, and a portion, which extends in the Y-axis direction, of the sides of the rectangle may be parallel to the extension direction of the lead 110.

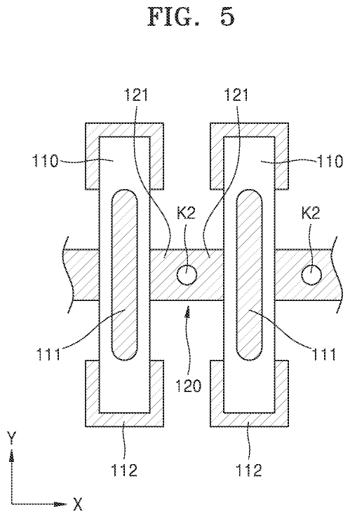

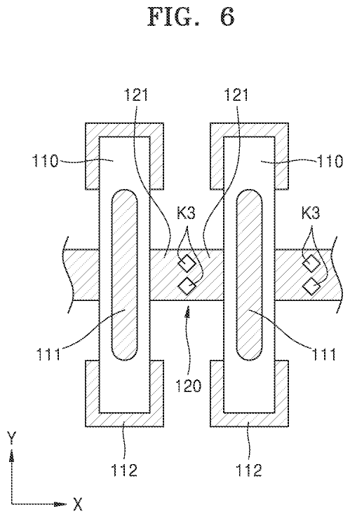

According to the present embodiment, although the shape of the upper surface K1 of the thickest portion G of the dambar 120 is a rectangle, the present disclosure is not limited thereto. In other words, according to the present disclosure, there is no special restriction to the shape or number of the upper surface of the thickest portion G of the dambar 120. For example, as illustrated in FIG. 5, the shape of an upper surface K2 of the thickest portion G of the dambar 120 may be a circle. Furthermore, as illustrated in FIG. 6, the shape of an upper surface K3 of the thickest portion G of the dambar 120 may be a polygon, and the polygon may include a plurality of polygons.

The structure of the dambar 120 of the lead frame 100 according to the present embodiment has the following operations and effects.

In the case of the present embodiment, the dambar groove 121 is formed between the thickest portion G of the dambar 120 and the lead 110 neighboring the thickest portion G of the dambar 120. Due to such a structure, in an etching process of manufacturing the lead frame 100, an etching material infiltrates along the dambar groove 121 to uniformly etch a side surface S of the lead 110, and thus the straightness of the side surface S of the lead 110 may be improved, thereby improving the quality of a lead frame.

Furthermore, due to the improved infiltration of an etching material, the volume of the dambar 120 is sufficiently reduced after the etching process. Then, later, not only a sawing process for singulation of the semiconductor package 10 may be smoothly performed, but also burr generation in the sawing process may be reduced. In other words, later, in the sawing process for singulation of the semiconductor package 10, a portion indicated by a dashed line in FIG. 3 is to be removed by sawing, and as the volume of the dambar 120 increases, the sawing process becomes more difficult and the burr generation is increased further. In the present embodiment, as the volume of the dambar 120 is sufficiently reduced, the amount of the dambar 120 removed in the sawing process is reduced, and thus the sawing process is facilitated, the life of a sawing blade increases, and the burr generation is reduced.

The die pad 130 is a portion corresponding to the position of a semiconductor chip, and the pad support portion 140 is a portion that supports the die pad 130.

The mold resin 150, which is an encapsulation material, may adopt a general electrical insulating material used in the semiconductor package 10. Examples of a material of the mold resin 150 may include an epoxy material, a urethane-based material, and the like.

To further clarify the above-described operations and effects of the present embodiment, a dambar structure of a general lead frame according to the related art that is compared with the dambar structure of the lead frame according to the present embodiment is described below as a comparative example.

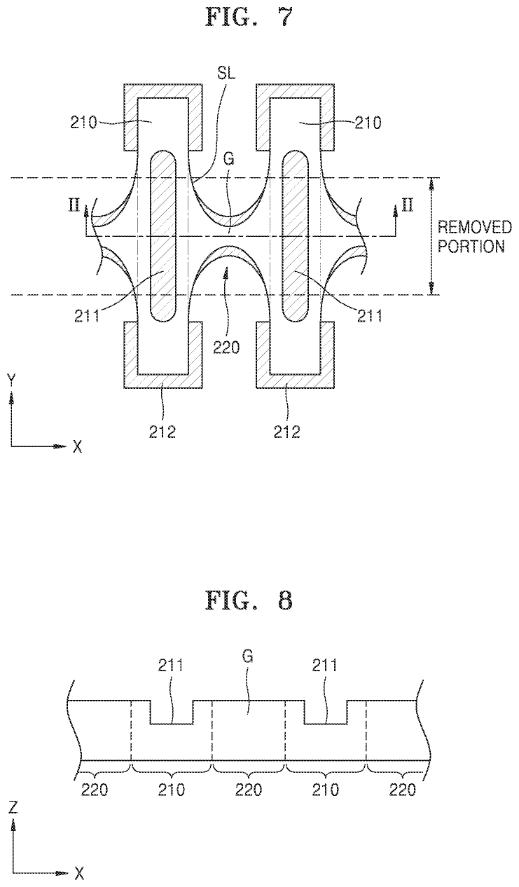

FIG. 7 is a schematic view of a lead and a dambar of a lead frame according to a comparative example for comparison with the present disclosure. FIG. 8 is a schematic cross-sectional view taken along line II-II of FIG. 7.

FIG. 7 illustrates a lead 210 and a dambar 220 of the lead frame according to a comparative example. A lead groove 211 is formed in the lead 210, and a half etching portion 212 is formed. As the lead groove 211 and the half etching portion 212 according to a comparative example are practically the same as the lead groove 111 and the half etching portion 112 of the present embodiment, descriptions thereof are omitted.

As the lead 210 includes a side surface SL that is inclined with respect to the Y-axis, straightness of the lead 210 may deteriorate. This is because, in an etching process of manufacturing a lead frame, as an etching material is blocked by the structure of the dambar 220, etching is not sufficiently performed to the side surface of the lead 210.

In other words, in the dambar 220 according to the comparative example, the thickest portion G continuously extends in the X-axis direction to connect the leads 210. Accordingly, in the comparative example, there is no structure corresponding to the dambar groove 121 of the present embodiment.

The structure of the comparative example, during the etching process of manufacturing a lead frame, as the dambar 220 has a structure that blocks the movement of an etching material, there is a difficulty in etching the side surface of the lead 210. Accordingly, as the straightness of the lead 210 deteriorates, not only the quality of a lead frame deteriorates, but also the volume of the dambar 220 is still large even after the etching process. Thus, the sawing process for the singulation of a semiconductor package becomes difficult, and the burr generation occurs that much.

Unlike the comparative example, according to the lead frame 100 according to the present embodiment, as the dambar groove 121 is formed between the thickest portion G of the dambar 120 and the lead 110 that neighbors the same, in the etching process of manufacturing a lead frame, the etching material moves along the dambar groove 121 so that etching is uniformly performed to the side surface S of the lead 110. Then, the straightness of the side surface S of the lead 110 is improved so that the quality of a lead frame may be improved, and due to the improved infiltration of an etching material, the volume of the dambar 120 may be sufficiently reduced after the etching process, so that the sawing process for the singulation of a semiconductor package may be smoothly performed and the burr generation may be reduced as well.

While the disclosure has been particularly shown and described with reference to preferred embodiments using specific terminologies, the embodiments and terminologies should be considered in descriptive sense only and not for purposes of limitation. Therefore, it will be understood by those of ordinary skill in the art that various changes in form and details may be made therein without departing from the spirit and scope of the disclosure as defined by the following claims.

### INDUSTRIAL APPLICABILITY

The lead frame according to the present embodiment is applicable to the lead frame manufacturing industry.

1. A lead frame comprising:
a plurality of lead with a lead groove formed therein; and
a dambar arranged between the leads to connect the leads,
wherein a thickness of the dambar arranged between the leads has at least two thickness values, and
a dambar groove is formed between a thickest portion of the dambar and the lead neighboring the thickest portion of the dambar.

2. The lead frame of claim 1, wherein the lead groove is applied to a wettable flank structure.

3. The lead frame of claim 1, wherein a thickness of a thickest portion of the lead is a same as a thickness of the thickest portion of the dambar.

4. The lead frame of claim 1, wherein a thickness of a portion of the lead where the lead groove is formed is a same as a thickness of a portion of the dambar where the dambar groove is formed.

5. The lead frame of claim 1, wherein a shape of an upper surface of the thickest portion of the dambar is a rectangle.

6. The lead frame of claim 5, wherein a part of sides of the rectangle is parallel to an extension direction of the lead.

7. The lead frame of claim 1, wherein a shape of an upper surface of the thickest portion of the dambar is a circle.

8. The lead frame of claim 1, wherein a shape of an upper surface of the thickest portion of the dambar is a polygon.
